(19) United States
(12) Patent Application Publication
(10) Pub. No.: US 2026/0176748 A1
(43) Pub. Date: Jun. 25, 2026

(54) ALUMINUM BOROHYDRIDE AMINE COORDINATION COMPOUNDS

(71) Applicant: ASM IP Holding B.V., Almere (NL)

(72) Inventors: Patricio Eduardo Romero, Boutersem (BE); Charles Dezelah, Helsinki (FI)

(21) Appl. No.: 19/426,358

(22) Filed: Dec. 19, 2025

Related U.S. Application Data
(60) Provisional application No. 63/738,659, filed on Dec. 24, 2024.

(51) Int. Cl. C23C 16/20; C07F 5/06; C23C 16/02; C23C 16/52

(52) U.S. Cl. CPC C23C 16/20; C07F 5/069; C23C 16/0272; C23C 16/52

(57) ABSTRACT

The present invention relates to compositions comprising a borohydride coordination compound, to a precursor vessel comprising the borohydride coordination compound, and to a method and a system for vapor deposition wherein the borohydride coordination compound is used, for depositing metal boride or metallic films. The borohydride coordination compound has a chemical formula MH₃₋ₓ(BH₄)ₓ(NR¹R²R³), wherein M is a Group 13 metal, wherein x has a value of 2 or 3, and:
wherein R¹ and R² are each independently selected from C1 to C8 alkyl groups, and wherein R³ is a C2 to C8 alkyl group, or
wherein R¹ together with R² and N forms a four to nine membered ring, and:
   R³ is selected from C1 to C8 alkyl groups, or
   R³ together with R² and N forms a four to nine membered ring.

### CROSS-REFERENCE TO RELATED APPLICATIONS

This application claims priority to U.S. Provisional Patent Application Ser. No. 63/738,659 filed Dec. 24, 2024 titled ALUMINUM BOROHYDRIDE AMINE COORDINATION COMPOUNDS, the disclosure of which is hereby incorporated by reference in its entirety.

### TECHNICAL FIELD OF THE INVENTION

The present invention relates to the field of materials science and thin film deposition technologies.

### BACKGROUND OF THE INVENTION

Metal gate electrodes are integral components in modern field-effect transistor (FET) devices, playing a crucial role in determining their electrical characteristics. As semiconductor technology advances, there is an increasing demand for materials and processes that can precisely control the threshold voltage of these metal gates to enhance device performance and scalability. Thin films of materials capable of shifting or optimizing the threshold voltage are particularly significant for the development of future FET architectures.

Metal borides, which may be represented by the general formula MBₓ, where x ranges from 2 to 6, have been identified as promising candidates for applications requiring shifting or optimizing of the threshold voltage. Specifically, borides of Group 2 metals, such as Mg, borides of transition metals, in particular those from Groups 3, 4, 5, and 6 of the Periodic Table, as well as borides of the lanthanides, or, more specifically, rare-earth metals, exhibit properties that are advantageous for such applications. These materials offer a range of work functions and electrical resistivities, making them valuable for gate-stack engineering.

Despite their potential, the deposition of high-quality metal boride thin films presents significant challenges. Atomic layer deposition (ALD) is a preferred method for producing uniform and conformal thin films, but there are currently very few ALD processes that can reliably form metal boride layers with the desired properties. Specifically, the development of suitable precursors that are both thermally stable and volatile is a critical hurdle. The lack of effective precursors and well-behaved ALD processes limits the ability to produce these metal boride films at the scale and quality required for semiconductor applications.

Moreover, there is a broader need for efficient methods to deposit pure transition metals, in particular those from Groups 3, 4, 5, and 6 of the Periodic Table, as well as the lanthanides, or, more specifically, rare-earth metals. Existing techniques often face limitations in terms of precursor availability, thermal stability, and reactivity, which can impact the purity and properties of the deposited metal films. Overcoming these challenges is essential for advancing semiconductor device fabrication and enabling the next generation of electronic devices.

However, despite the progress in this field, there remains a need for further advancements to address at least some of these challenges.

### SUMMARY OF THE INVENTION

It is an objective of the present invention to provide a good precursor for depositing a material.

The above objective is accomplished by a precursor, a precursor vessel, a method, and a system according to the present invention.

It is an advantage of embodiments of the present invention that new thermally stable and volatile aluminum borohydride precursors or co-reactants are provided as boron or hydride sources, facilitating the formation of metal boride layers or substantially pure metal layers.

It is an advantage of embodiments of the present invention that a method is offered to deposit metal borides alongside easily accessible coordination compounds, e.g., metal diketonates.

In a first aspect, the present invention relates to a composition comprising a borohydride coordination compound with a chemical formula MH₃₋ₓ(BH₄)ₓ(NR¹R²R³), wherein M is a Group 13 metal, wherein x has a value of 2 or 3, and:
wherein R¹ and R² are each independently selected from C1 to C8 alkyl groups, and wherein R³ is a C2 to C8 alkyl group, or
wherein R¹ together with R² and N forms a four to nine membered ring, and:
   R³ is selected from C1 to C8 alkyl groups, or
   R³ together with R² and N forms a four to nine membered ring.

In a second aspect, the present invention relates to a precursor vessel comprising a chemical precursor comprising a borohydride coordination compound with a chemical formula MH₃₋ₓ(BH₄)ₓ(NR¹R²R³), wherein M is a Group 13 metal, wherein x has a value of 2 or 3, and:
wherein R¹, R², and R³ are each independently selected from C1 to C8 alkyl groups, or
wherein R¹ together with R² and N forms a four to nine membered ring, and:
   R³ is selected from C1 to C8 alkyl groups, or
   R³ together with R² and N forms a four to nine membered ring,
   wherein the precursor vessel is configured to supply a vapor comprising the chemical precursor to a reaction chamber of a vapor deposition system.

In a third aspect, the present invention relates to a method for depositing a material on a substrate, the method comprising:
providing a substrate in a reaction chamber, and then
providing, into the reaction chamber, a vapor-phase borohydride precursor comprising a borohydride coordination compound with a chemical formula MH₃₋ₓ(BH₄)ₓ(NR¹R²R³), wherein M is a Group 13 metal, wherein x has a value of 2 or 3, and:
   wherein R¹, R², and R³ are each independently selected from C1 to C8 alkyl groups, or
   wherein R¹ together with R² and N forms a four to nine membered ring, and:
R³ is selected from C1 to C8 alkyl groups, or
R³ together with R² and N forms a four to nine membered ring,
thereby forming a first thin film comprising at least a portion of the borohydride coordination compound on a portion of a surface of the substrate.

In a fourth aspect, the present invention relates to a system for depositing a material, the system comprising:
a reaction chamber for receiving the substrate,
a first source, connected via a first valve to the reaction chamber, for providing a vapor-phase borohydride precursor comprising a borohydride coordination compound with a chemical formula MH₃₋ₓ(BH₄)ₓ(NR¹R²R³), wherein M is a Group 13 metal, wherein x has a value of 2 or 3, and:
   wherein R¹, R² and R³ are each independently selected from C1 to C8 alkyl groups, or
   wherein R¹ together with R² and N forms a four to nine membered ring, and:
      R³ is selected from C1 to C8 alkyl groups, or
      R³ together with R² and N forms a four to nine membered ring, and
a controller operably connected to the first valve, wherein the controller is configured and programmed to open the first valve to provide a flow of the vapor-phase borohydride precursor into the reaction chamber and to close the first valve to cease the flow of the vapor-phase borohydride precursor into the reaction chamber.

In a fifth aspect, the present invention relates to a composition configured for depositing a thin film, the composition comprising a chemical precursor comprising a borohydride coordination compound with a chemical formula MH₃₋ₓ(BH₄)ₓ(NR¹R²R³), wherein M is a Group 13 metal, wherein x has a value of 2 or 3, and:
wherein R¹, R² and R³ are each independently selected from C1 to C8 alkyl groups, or
wherein R¹ together with R² and N forms a four to nine membered ring, and:
   R³ is selected from C1 to C8 alkyl groups, or
   R³ together with R² and N forms a four to nine membered ring.

Particular and preferred aspects of the invention are set out in the accompanying independent and dependent claims. Features from the dependent claims may be combined with features of the independent claims and with features of other dependent claims as appropriate and not merely as explicitly set out in the claims.

Although there has been constant improvement, change and evolution of devices in this field, the present concepts are believed to represent substantial new and novel improvements, including departures from prior practices, resulting in the provision of more efficient, stable and reliable devices of this nature.

The above and other characteristics, features and advantages of the present invention will become apparent from the following detailed description, taken in conjunction with the accompanying drawings, which illustrate, by way of example, the principles of the invention. This description is given for the sake of example only, without limiting the scope of the invention. The reference figures quoted below refer to the attached drawings.

### BRIEF DESCRIPTION OF THE DRAWINGS

FIG. 1 is a schematic representation of a deposition system in accordance with embodiments of the present invention.

FIG. 2 is a schematic representation of a surface of a substrate in a method in accordance with embodiments of the present invention, with a metal precursor in accordance with embodiments of the present invention provided over the surface.

FIG. 3 is a schematic representation of the surface of the substrate of FIG. 2, after reaction with the metal precursor.

FIG. 4 is a schematic representation of the surface of the substrate of FIG. 3, with a borohydride precursor in accordance with embodiments of the present invention over the surface.

FIG. 5 is a schematic representation of the surface of the substrate of FIG. 4, after reaction with the borohydride precursor comprising transfer of a borohydride to the metal precursor.

FIG. 6 is a schematic representation of a film formed on a substrate in the reaction chamber of the deposition system of FIG. 1.

FIG. 7 is a schematic representation of the surface of the substrate of FIG. 5, after reaction with the borohydride precursor comprising transfer of a hydride to the metal precursor.

In the different figures, the same reference numerals refer to the same or analogous elements.

### DESCRIPTION OF ILLUSTRATIVE EMBODIMENTS

The present invention will be described with respect to particular embodiments and with reference to certain drawings, but the invention is not limited thereto and is limited only by the claims. The drawings described are only schematic and are non-limiting. In the drawings, the size of some of the elements may be exaggerated and not drawn to scale for illustrative purposes. The dimensions and the relative dimensions do not correspond to actual reductions to practice of the invention.

Furthermore, the terms first, second, third and the like in the description and in the claims, are used for distinguishing between similar elements and not necessarily for describing a sequence, either temporally, spatially, in ranking or in any other manner. It is to be understood that the terms so used are interchangeable under appropriate circumstances and that the embodiments of the invention described herein are capable of operation in other sequences other than described or illustrated herein.

Moreover, the terms top, bottom, over, under and the like in the description and the claims are used for descriptive purposes and not necessarily for describing relative positions. It is to be understood that the terms so used are interchangeable under appropriate circumstances and that the embodiments of the invention described herein are capable of operation in other orientations than described or illustrated herein.

It is to be noticed that the term “comprising”, used in the claims, should not be interpreted as being restricted to the means listed thereafter; it does not exclude other elements or steps. It is thus to be interpreted as specifying the presence of the stated features, integers, steps or components as referred to, but does not preclude the presence or addition of one or more other features, integers, steps or components, or groups thereof. The term “comprising” therefore covers the situation where only the stated features are present and the situation where these features and one or more other features are present. The word “comprising” according to the invention therefore also includes as one embodiment that no further components are present. Thus, the scope of the expression “a device comprising means A and B” should not be interpreted as being limited to devices consisting only of components A and B. It means that with respect to the present invention, the only relevant components of the device are A and B. The term “comprises” may encompass, however, also, in the limit of “no other elements or steps present”, the term “consists of”, so that the term “comprises” may be understood to provide basis for replacing the term “comprises” by “consists of” as well.

Similarly, it is to be noticed that the term “coupled” should not be interpreted as being restricted to direct connections only. The terms “coupled” and “connected”, along with their derivatives, may be used. It should be understood that these terms are not intended as synonyms for each other. Thus, the scope of the expression “a device A coupled to a device B” should not be limited to devices or systems wherein an output of device A is directly connected to an input of device B. It means that there exists a path between an output of A and an input of B which may be a path including other devices or means. “Coupled” may mean that two or more elements are either in direct physical or electrical contact, or that two or more elements are not in direct contact with each other but yet still co-operate or interact with each other.

Reference throughout this specification to “one embodiment” or “an embodiment” means that a particular feature, structure or characteristic described in connection with the embodiment is included in at least one embodiment of the present invention. Thus, appearances of the phrases “in one embodiment” or “in an embodiment” in various places throughout this specification are not necessarily all referring to the same embodiment, but may. Furthermore, the particular features, structures or characteristics may be combined in any suitable manner, as would be apparent to one of ordinary skill in the art from this disclosure, in one or more embodiments.

Similarly, it should be appreciated that in the description of exemplary embodiments of the invention, various features of the invention are sometimes grouped together in a single embodiment, figure, or description thereof for the purpose of streamlining the disclosure and aiding in the understanding of one or more of the various inventive aspects. This method of disclosure, however, is not to be interpreted as reflecting an intention that the claimed invention requires more features than are expressly recited in each claim. Rather, as the following claims reflect, inventive aspects lie in less than all features of a single foregoing disclosed embodiment. Thus, the claims following the detailed description are hereby expressly incorporated into this detailed description, with each claim standing on its own as a separate embodiment of this invention.

Furthermore, while some embodiments described herein include some but not other features included in other embodiments, combinations of features of different embodiments are meant to be within the scope of the invention, and form different embodiments, as would be understood by those in the art. For example, in the following claims, any of the claimed embodiments can be used in any combination.

Furthermore, some of the embodiments are described herein as a method or combination of elements of a method that can be implemented by a processor of a computer system or by other means of carrying out the function. Thus, a processor with the necessary instructions for carrying out such a method or element of a method forms a means for carrying out the method or element of a method. Furthermore, an element described herein of an apparatus embodiment is an example of a means for carrying out the function performed by the element for the purpose of carrying out the invention.

In the description provided herein, numerous specific details are set forth. However, it is understood that embodiments of the invention may be practiced without these specific details. In other instances, well-known methods, structures and techniques have not been shown in detail in order not to obscure an understanding of this description.

The following terms are provided solely to aid in the understanding of the invention.

As used herein, and unless otherwise specified, the term “layer” and/or (thin) “film” can refer to any continuous or non-continuous material, such as material deposited by the methods disclosed herein. For example, a layer and/or a film can include two-dimensional materials, three-dimensional materials, nanoparticles or even partial or full molecular layers or partial or full atomic layers, or clusters of atoms and/or molecules. A film or layer may comprise material or a layer with pinholes, which may be at least partially continuous. In some embodiments, a layer according to the current disclosure is substantially continuous.

As used herein, a “substrate” refers to an underlying material or materials that may be used to form, or upon which, a device, a circuit, a material, or a material layer may be formed. The substrate may be continuous or non-continuous; rigid or flexible; solid or porous; and combinations thereof. The substrate may be in any form, such as, for example, a powder, a sheet, a plate, or a workpiece. Substrates in the form a sheet may extend beyond the bounds of a process/reaction chamber where a deposition process occurs and, in some cases, move through the chamber such that the process continues until the end of the substrate is reached. Substrates in the form of a plate may include wafers in various shapes and sizes. Substrates may be made from semiconductor materials, including, for example, Mo, Mo germanium, Mo oxide, gallium arsenide, gallium nitride, and Mo carbide. A substrate can include one or more layers overlying a bulk material, for example the substrate may include nitrides, for example TiN, oxides, insulating materials, dielectric materials, conductive materials, metals, such as tungsten, ruthenium, Group 6 metal, cobalt, aluminum, or copper, or other metallic materials, crystalline materials, epitaxial, heteroepitaxial, and/or single crystal materials. The substrate can include various topologies, such as, for example, gaps, recesses, lines, trenches, vias, holes, or spaces between elevated portions, such as fins, and the like formed within or on at least a portion of a layer of the substrate.

The standard abbreviations of the elements in the periodic table are used herein.

The invention will now be described by a detailed description of several embodiments of the invention. It is clear that other embodiments of the invention can be configured according to the knowledge of persons skilled in the art without departing from the technical teaching of the invention, the invention being limited only by the terms of the appended claims.

In a first aspect, the present invention relates to a composition comprising a borohydride coordination compound with a chemical formula MH₃₋ₓ(BH₄)ₓ(NR¹R²R³), wherein M is a Group 13 metal, wherein x has a value of 2 or 3, and:
wherein R¹ and R² are each independently selected from C1 to C8 alkyl groups, and wherein R³ is a C2 to C8 alkyl group, or
wherein R¹ together with R² and N forms a four to nine membered ring, and:
   R³ is selected from C1 to C8 alkyl groups, or
   R³ together with R² and N forms a four to nine membered ring.

In some embodiments, M may be selected from a group consisting of: aluminum, gallium, and indium. In some embodiments, M may be aluminum. In particular, aluminum facilitates effective transmetallation with transition metals.

In some embodiments, x may have a value of 3. These embodiments provide an optimal boron content for metal boride formation. Furthermore, in these embodiments, the borohydride coordination compound may be particularly stable.

In some embodiments, x may have a value of 1.

The amine NR¹R²R³ may provide the borohydride coordination compound with good thermal stability. Therefore, the borohydride coordination compound may be particularly useful in deposition techniques, which may be performed at elevated temperatures.

In some embodiments, R¹ and R² may be each independently selected from C1 to C3 alkyl groups and R³ may be a C2 to C4 alkyl group. In some embodiments, R¹ and R² may be each independently selected from C1 to C2 alkyl groups and R³ may be a C2 to C3 alkyl group. In some embodiments, R¹ and R² may be methyl groups and R³ may be an ethyl group. The inventors have found that this specific combination of alkyl groups may be particularly effective, conferring good thermal stability to the precursor, whereas it does substantially not interfere with deposition processes in which the borohydride coordination compound is used.

In some embodiments, R¹, R², and N together may form a five or six membered ring, and R³ may be a C1 to C6 alkyl group. In some embodiments, R¹, R², and N together may form a five membered ring, and R³ may be a C1 to C3 alkyl group. In some embodiments, NR¹R²R³ may be N-methyl-pyrrolidine.

In some embodiments, R¹ together with R² and N forms a four to nine membered ring, and R³ together with R² and N forms a four to nine membered ring. In some embodiments, R¹ together with R² and N forms a four to six membered ring, and R³ together with R² and N forms a four to six membered ring. In some embodiments, NR¹R²R³ may be quinuclidine.

The borohydride coordination compound may be obtained by any technique known to the skilled person. As an example, the borohydride coordination compound with x=3 may be formed by reacting a borohydride of the Group 13 metal with NR¹R²R³, which may directly yield the borohydride coordination compound of the first aspect. As another example, the borohydride coordination compound with x=1, 2 or 3 may be formed by reacting MH₃ with NR¹R²R³, forming AlH₃(NR¹R²R³), which may in turn be exposed to a vapor of BH₃. Thereby, the borohydride coordination compound with x=1, 2 or 3 may be formed.

Preferably, the borohydride coordination compound may be obtained by reacting a halide of the Group 13 metal, e.g., AlCl₃, with NR¹R²R³, to form a compound in which Group 13 metal of the halide is complexed to the NR¹R²R³ group, e.g., to form R¹R²R³N—AlCl₃. The thus formed compound may then be reacted with a borohydride source such as LiBH₄ in the appropriate stoichiometric ratio to form the borohydride coordination compound of the present invention. For said reaction, LiBH₄ may be provided, for example, in any ethereal solvent, including but not limited to diethyl ether, methyl-tert-butyl ether, dimethoxyethane, tetrahydrofuran, or dioxane. LiBH₄ is preferred as it is soluble enough to carry the reaction to completion. The thus formed borohydride coordination compound may be distilled, sublimed and/or crystallized for purification, depending on their physical properties.

Any features of any embodiment of the first aspect may be independently combined as correspondingly described for any embodiment of any of the other aspects of the present invention.

In a second aspect, the present invention relates to a precursor vessel comprising a borohydride precursor comprising a borohydride coordination compound with a chemical formula MH₃₋ₓ(BH₄)ₓ(NR¹R²R³), wherein M is a Group 13 metal, wherein x has a value of 2 or 3, and:
wherein R¹, R², and R³ are each independently selected from C1 to C8 alkyl groups, or
wherein R¹ together with R² and N forms a four to nine membered ring, and:
   R³ is selected from C1 to C8 alkyl groups, or
   R³ together with R² and N forms a four to nine membered ring,
wherein the precursor vessel is configured to supply a vapor comprising the borohydride precursor to a reaction chamber of a vapor deposition system, such as a semiconductor processing apparatus chamber.

In some embodiments of the present invention, x may have a value of 1.

The precursor vessel may be fabricated of a suitable vessel material, such as stainless steel, aluminum, copper, nickel, silver, their alloys, graphite, boron nitride, ceramic material or a combination or a mixture of said materials. The vessel material may be a heat-conducting material. The vessel material may be a coated or clad material.

The precursor vessel comprises a housing defining an interior volume of the precursor vessel. The interior volume is adapted for holding the borohydride precursor according to embodiments of the present invention. In some embodiments, the interior volume has a substantially circular cylindrical shape, so that the interior volume has a substantially circular floor. However, the interior volume of the precursor vessel may have any shape that facilitates an even flow of vapor-phase borohydride precursor and optional carrier gas through the interior volume. In some embodiments, the precursor vessel may have a height to width aspect ratio in the range of about 0.5 to 4, for example 1 to 2 or 1 to 3. The height of the precursor vessel is a dimension at an exterior of the precursor vessel from a lid to a portion of the housing farthest away from the lid. The width of the precursor vessel is a largest dimension across the precursor vessel perpendicular to the height.

In some embodiments, the precursor vessel comprises a lid for isolating the interior volume from the surrounding atmosphere. In some embodiments, the lid may comprise an inlet for feeding a, typically inert, carrier gas (e.g., N₂, He or Ar) into the interior volume of the precursor vessel. The inlet for feeding the carrier gas may comprise an inlet valve for introducing said carrier gas when the inlet valve is open, and for blocking said carrier gas from being fed into the precursor vessel when the inlet valve is closed. The lid may comprise an outlet for feeding the borohydride precursor, and optionally the carrier gas, to the reaction chamber. The outlet may comprise an outlet valve for providing said borohydride precursor, and the optional carrier gas, to the reaction chamber when the outlet valve is open, and for blocking said borohydride precursor, and the optional carrier gas, from being fed to the reaction chamber when the outlet valve is closed.

The precursor vessel may be provided with gas lines extending from the inlet and outlet, isolation valves on the lines, and fittings on the valves, the fittings being configured to connect to gas flow lines of other components of a chemical vapor deposition system. Isolation valves may fluidically isolate the contents of the precursor vessel from the vessel exterior. One isolation valve may be provided upstream of the precursor vessel inlet, and another isolation valve may be provided downstream of the precursor vessel outlet.

The precursor vessel, or a deposition system of which the precursor vessel may be part, may comprise a heater, such as radiant heat lamps or resistive heaters. In some embodiments, the heater may be adapted to heat the precursor vessel to a temperature of from 40° C. to 200° C., for example, to 70° C., 85° C., 90° C., 110° C. or 120° C. In particular during use of the precursor vessel in a vapor deposition method, the heater may be configured to heat up the precursor vessel to a temperature above a volatilization temperature, under a pressure within the precursor vessel, of the borohydride precursor.

In some embodiments, the pressure within the precursor vessel may be from 10 to 1000 Pa, although the invention is not limited thereto. In particular during use in a chemical vapor deposition method, precursor vessels are typically at such a low pressure. The precursor vessel may comprise, or may be coupled to, a pressure control system, for monitoring a pressure in the precursor vessel. The precursor vessel may comprise a valve for coupling the precursor vessel to a vacuum pump.

In some embodiments, the precursor vessel may comprise precursor distribution means for enabling efficient borohydride precursor vaporization, e.g., precursor holding structures or carrier gas guiding arrangements in the interior volume of the precursor vessel. The precursor vessel may comprise features for filtering solid particles, to prevent such particles from being present in the vapor phase flow, such as filters or other entrapment structures. Additionally, the inlet and the outlet of the precursor vessel, as well as gas lines extending therefrom, may comprise heaters for heating the valves and gas lines between the precursor vessel and the reaction chamber to prevent the borohydride precursor vapor from condensing and depositing on any components.

Any features of any embodiment of the second aspect may be independently combined as correspondingly described for any embodiment of any of the other aspects of the present invention.

In a third aspect, the present invention relates to a method for depositing a material on a substrate, the method comprising:
providing a substrate in a reaction chamber, and then
providing, into the reaction chamber, a vapor-phase borohydride precursor comprising a borohydride coordination compound with a chemical formula MH₃₋ₓ(BH₄)ₓ(NR¹R²R³), wherein M is a Group 13 metal, wherein x has a value of 2 or 3, and:
   wherein R¹, R², and R³ are each independently selected from C1 to C8 alkyl groups, or
   wherein R¹ together with R² and N forms a four to nine membered ring, and:
R³ is selected from C1 to C8 alkyl groups, or
R³ together with R² and N forms a four to nine membered ring,
thereby forming a first thin film comprising at least a portion of the borohydride coordination compound on a portion of a surface of the substrate.

In some embodiments, the first thin film may comprise the borohydride coordination compound on the portion of the surface of the substrate. In some embodiments, the first thin film may comprise the portion of the borohydride coordination compound on the portion of the substrate. In some embodiments, the first thin film may comprise a borohydride (BH₄) from the borohydride coordination compound, or a hydride from the borohydride coordination compound. In some embodiments, said hydride may originate from a borohydride of the borohydride coordination compound or may be a borohydride bonded to the Group 13 metal of the borohydride coordination compound.

In some embodiments, the method may comprise—before providing the vapor-phase borohydride precursor into the reaction chamber—a step of:
providing, into the reaction chamber, a metal vapor-phase precursor comprising a metal coordination compound comprising:
   a Group 2, transition, or lanthanide metal, and
   a substitutionally labile ligand,
thereby forming a second thin film comprising the Group 2, transition, or lanthanide metal bonded to the ligand on a portion of a surface of the substrate,
wherein said providing of the vapor-phase borohydride precursor into the reaction chamber comprises replacing, or substituting, the substitutionally labile ligand of the second thin film with the borohydride or a hydride, thereby forming the first film.

This two-step process may provide deposition via transmetallation. It is an advantage of these embodiments that said transmetallation process allows the method to deposit—as a metal or boride—a wide range of semiconductor-relevant metals, particularly rare-earths.

When the substitutionally labile ligand is replaced with the borohydride, i.e., BH₄, from the borohydride coordination compound, typically, the material to be deposited is a boride of the Group 2, transition, or lanthanide metal. The hydrogen atoms of the borohydride on the surface may be removed, while leaving the boron bonded to the Group 2, transition, or lanthanide metal on the surface, to yield the boride of the Group 2, transition, or lanthanide metal. This removal of the hydrogen atoms may be performed by any technique known to the skilled person. For example, the hydrogen atoms may be removed spontaneously or by thermal elimination, breaking bonds between the Group 2, transition, or lanthanide metal and hydrogen atoms, thereby forming a metal boride and releasing H₂ as a gas. Alternatively, a vapor-phase co-reactant may be provided into the reaction chamber for removing the hydrogen atoms of the borohydride on the surface, such as ammonia, or hydrazine, or organic hydrogen scavengers such as trimethylaluminum. A hydrogen gas plasma may be provided, generating H— radicals that recombine with, and desorb, surface hydrogen as H₂ gas. Still alternatively, the hydrogen atoms of the borohydride on the surface may be removed during a cyclic process of cyclically providing the metal precursor and then the borohydride precursor. For example, the hydrogen atoms of the borohydride may react with the substitutionally labile ligand of the metal precursor, for example, when the substitutionally labile ligand is a halide (e.g., chloride). In this process of removing the hydrogen atoms, bonds between the boron atoms and the Group 2, transition, or lanthanide metal, and between the boron atoms, may be formed.

When, instead, the substitutionally labile ligand on the surface is replaced with the hydride, typically, reduction of the Group 2, transition, or lanthanide metal occurs and the deposited material that is formed may be a metal. Herein, the hydride may originate from the borohydride of the borohydride coordination compound, or may be one of the hydrides originally directly bonded to the Group 13 metal of the borohydride coordination compound. In particular embodiments, both replacement of the substitutionally labile ligand by the borohydride and by the hydride may occur. The hydrogen atoms on the surface, i.e., the surface hydrogen atoms, bonded to the Group 2, transition, or lanthanide metal, may be removed by similar techniques to those mentioned above for removing the hydrogen atoms from the borohydride bonded to the Group 2, transition, or lanthanide metal.

Whether borides of the Group 2, transition, or lanthanide metal are formed, or reduction to the, pure or metallic, Group 2, transition, or lanthanide metal occurs, will, for example, depend on the reduction potential of the Group 2, transition, or lanthanide metal, the relative stability of the deposited boride compared to the deposited metal, and on the selection of the ligands. In some cases, the combination of a particular borohydride coordination compound and Group 2, transition, or lanthanide metal coordination compound strongly favors the formation of a metal boride or a metal, but in some cases reaction conditions may be tuned so as to optimize the formation of a metal boride or a metal.

In some embodiments, the metal coordination compound comprises the Group 2, transition, or lanthanide metal and one or more ligands. In some embodiments, the Group 2, transition, or lanthanide metal comprises a transition or lanthanide metal. In some embodiments, the Group 2 metal is Mg. In some embodiments, the Group 2, transition, or lanthanide metal is selected from a group consisting of: Sc, Y, La, Ce, Pr, Nd, Pm, Sm, Eu, Gd, Tb, Dy, Ho, Er, Tm, Yb, and Lu. In some embodiments, the Group 2, transition, or lanthanide metal is selected from a group consisting of: Mg, Ti, Zr, and Hf. In some embodiments, the Group 2, transition, or lanthanide metal is selected from a group consisting of: V, Nb, Ta, Cr, Mo, and W. In some embodiments, the borohydride coordination compound comprises a Group 13 metal M′ and a borohydride (BH₄) ligand. In some embodiments, the Group 13 metal is selected from a group consisting of the following elements: Al, Ga, and In. In preferred embodiments, the borohydride coordination compound is Al(BH₄)₃(NMe₂Et). In these embodiments, the reaction, in, e.g., a method of atomic layer deposition or chemical vapor deposition, of the borohydride coordination compound and the metal coordination compound may result in the formation of a metal boride thin film.

In some embodiments, the Group 2, transition, or lanthanide metal comprises a transition or lanthanide metal. In some embodiments, the Group 2, transition, or lanthanide metal is selected from: Mo, W, Re, Ru, Co, Rh, Ir, Ni, Pd, Pt, Cu, Ag, and Au. In some embodiments, the Group 13 metal is selected from a group consisting of: Al, Ga, and In. In preferred embodiments, the borohydride coordination compound is Al(BH₄)₃(NMe₂Et). In some embodiments, the reaction, in, e.g., a method of atomic layer deposition or chemical vapor deposition, of the borohydride coordination compound and the metal coordination compound may result in the formation of a metallic, thin film of the Group 2, transition, or lanthanide metal.

In some embodiments, the metal coordination compound comprises one or more substitutionally labile ligands L. In some embodiments, the metal coordination compound comprises at least two substitutionally labile ligands L. In some embodiments, the metal coordination compound comprises from two to six substitutionally labile ligands L.

In some embodiments, the metal coordination compound may comprise further ligands that are not substitutionally labile, e.g., that are not replaceable by transmetallation. Such further ligands may, for example, provide thermal stability to the metal coordination compound, facilitate transmetallation, or may comprise molecules or atoms for incorporation into the film to be deposited. However, preferably, the metal coordination compound consists of the one or more substitutionally labile ligands L bonded to the Group 2, transition, or lanthanide metal.

In some embodiments, the substitutionally labile ligand may comprise a cyclopentadienyl type ligand, examples of which include cyclopentadienyl (Cp), methylcyclopentadienyl (MeCp), ethylcyclopentadienyl (EtCp), isopropylcyclopentadienyl (ⁱPrCp), tert-butylcyclopentadienyl (^{t}BuCp), trimethylsilylcyclopentadienyl (TMSCp), pentamethylcyclopentadienyl (Cp*), 1,2,4-triisopropylcyclopentadienyl (ⁱPr₃Cp), and 1,2,4-tri-tert-butylcyclopentadienyl (^{t}Bu₃Cp).

In some embodiments, the substitutionally labile ligand may comprise an amido type ligand, examples of which include dimethylamido (NMe₂), diethylamido (NEt₂), ethylmethylamido (NEtMe), diisopropylamido (NⁱPr₂), tert-butylamino (NH^{t}Bu), and bis(trimethylsilyl)amido (N(SiMe₃)₂).

In some embodiments, the substitutionally labile ligand may comprise an imido type ligand, examples of which include ethylimido (NEt), isopropylimido (NⁱPr), isobutylimido (NⁱBu), tert-butylimido (N^{t}Bu), and tert-pentylimido (N^{t}Pn).

In some embodiments, the substitutionally labile ligand may comprise an amidinate type ligand, examples of which include N,N′-diethylacetamidinate (Et₂AMD), N,N′-diisopropylacetamidinate (ⁱPr₂AMD), N,N′-diisopropylformamidinate (ⁱPr₂FMD), N,N′-di-tert-butylacetamidinate (^{t}Bu₂AMD), and N,N′-di-tert-butylformamidinate (tBu₂FMD).

In some embodiments, the substitutionally labile ligand may comprise a halide ligand, examples of which include fluoro (F), chloro (Cl), bromo (Br), and iodo (I).

In some embodiments, the substitutionally labile ligand may comprise an alkyl ligand, examples of which include methyl (Me), ethyl (Et), isopropyl (ⁱPr), tert-butyl (tBu), isobutyl (ⁱBu), tert-pentyl (tPn), and neopentyl (Np).

In some embodiments, the substitutionally labile ligand may comprise an alkoxide type ligand, examples of which include methoxide (OMe), ethoxide (OEt), isopropoxide (OiPr), tert-butoxide (OtBu), 1-methoxy-2-methyl-2-propoxide (mmp), 1-dimethylamino-2-propoxide (dmap), 1-dimethylamino-2-methyl-2-propoxide (dmamp), 1-ethylmethylamino-2-methyl-2-propoxide (emamp), 1-diethylamino-2-methyl-2-propoxide (deamp), 1-dimethylamino-2-methyl-2-butoxide (dmamb), 1-ethylmethylamino-2-methyl-2-butoxide (emamb), and 1-diethylamino-2-methyl-2-butoxide (deamb).

In some embodiments, the substitutionally labile ligand may be an enaminolate. The enaminolate ligand has the following chemical formula:

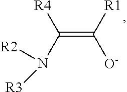

wherein R¹ may be hydrogen or a C1 to C8 alkyl group or an alkylsilyl group; R² and R³ may each be independently selected from C1 to C8 alkyl groups or alkylsilyl groups; and R⁴ may be hydrogen or a C1 to C8 alkyl group or an alkylsilyl group.

In some embodiments, the substitutionally labile ligand may comprise a diketonate type ligand, examples of which include acetylacetonate (acac), 2,2,6,6-tetramethylheptane-3,5-dionate (thd), and, 1,1,1,5,5,5-hexafluoropentane-2,5-dionate (hfac).

In some embodiments, the substitutionally labile ligand may comprise a diazabutadiene type ligand, examples of which include 1,4-di-tert-butyl-1,4-diaza-1,3-butadiene (^{t}Bu₂DAD), 1,4-diisopropyl-1,4-diaza-1,3-butadiene (ⁱPr₂DAD), 1,4-di-sec-butyl-1,4-diaza-1,3-butadiene (^{s}Bu₂DAD), and 1,4-di-tert-pentyl-1,4-diaza-1,3-butadiene (^{t}Pn₂DAD).

In some embodiments, the substitutionally labile ligand may be a monodentate ligand. In some embodiments, the substitutionally labile ligand may be a bidentate ligand. In some embodiments, the substitutionally labile ligand may be bonded with two atoms each independently selected from oxygen and nitrogen to the metal. In some embodiments, the substitutionally labile ligand may be a diketonate. In some embodiments, the substitutionally labile ligand may be an optionally substituted acetylacetonate. In some embodiments, the substitutionally labile ligand may be 2,2,6,6-tetramethyl-3,5-heptanedionate. It is an advantage of these embodiments that acetylacetonate-type ligands act as good leaving groups when coordinated to a transition metal, allowing for their exchange and transfer from the Group 2, transition, or lanthanide metal to the Group 13 metal in a transmetallation process.

In some embodiments, the Group 2, transition, or lanthanide metal may be selected from a group consisting of Group 3, Group 4, Group 5, and Group 6 metals, and lanthanides. In some embodiments, the Group 2, transition, or lanthanide metal may be a rare earth metal. Rare earth borides have promising properties for microelectronics. The rare earth metal may be selected from a list consisting of: scandium (Sc), yttrium (Y), lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), and lutetium (Lu).

In some embodiments, the metal coordination compound comprises at least one of, or may be selected from a list consisting of: ScCp₃, Sc(MeCp)₃, Sc(EtCp)₃, Sc(ⁱPrCp)₃, Sc(acac)₃, Sc(thd)₃, Sc(N(SiMe₃)₂)₃, Sc(Et₂AMD)₃, Sc(ⁱPr₂FMD)₃, Sc(ⁱPr₂AMD)₃, Sc(^{t}Bu₂FMD)₃, Sc(^{t}Bu₂AMD)₃, ScCp₂(ⁱPr₂FMD), Sc(MeCp)₂(ⁱPr₂FMD), Sc(EtCp)₂(ⁱPr₂FMD), Sc(ⁱPrCp)₂(ⁱPr₂FMD), ScCp₂(ⁱPr₂AMD), Sc(MeCp)₂(ⁱPr₂AMD), Sc(EtCp)₂(ⁱPr₂AMD), and Sc(ⁱPrCp)₂(ⁱPr₂AMD).

In some embodiments, the metal coordination compound comprises at least one of, or may be selected from a list consisting of: YCp₃, Y(MeCp)₃, Y(EtCp)₃, Y(ⁱPrCp)₃, Y(^{t}BuCp)₃, Y(thd)₃, Y(N(SiMe₃)₂)₃, Y(^{t}Bu₂FMD)₃, Y(^{t}Bu₂AMD)₃, Y(ⁱPr₂FMD)₃, Y(ⁱPr₂AMD)₃, YCp₂(ⁱPr₂AMD), YCp₂(^{t}Bu₂AMD), YCp₂(ⁱPr₂FMD), YCp₂(^{t}Bu₂FMD), Y(MeCp)₂(ⁱPr₂AMD), Y(MeCp)₂(^{t}Bu₂AMD), Y(MeCp)₂(ⁱPr₂FMD), Y(MeCp)₂(^{t}Bu₂FMD), Y(EtCp)₂(ⁱPr₂AMD), Y(EtCp)₂(^{t}Bu₂AMD), Y(EtCp)₂(ⁱPr₂FMD), Y(EtCp)₂(^{t}Bu₂FMD), Y(ⁱPrCp)₂(ⁱPr₂AMD), Y(ⁱPrCp)₂(^{t}Bu₂AMD), Y(ⁱPrCp)₂(ⁱPr₂FMD), and Y(ⁱPrCp)₂(^{t}Bu₂FMD).

In some embodiments, the metal coordination compound comprises at least one of, or may be selected from a list consisting of: LaCp₃, La(MeCp)₃, La(EtCp)₃, La(ⁱPrCp)₃, La(^{t}BuCp)₃, La(TMSCp)₃, La(thd)₃, La(N(SiMe₃)₂)₃, La(ⁱPr₂FMD)₃, La(^{t}Bu₂FMD)₃, La(^{s}Bu₂FMD)₃, La(^{t}Pn₂FMD)₃, La(ⁱPr₂AMD)₃, La(^{t}Bu₂AMD)₃, La(^{s}Bu₂AMD)₃, La(^{t}Pn₂AMD)₃, LaCp₂(ⁱPr₂AMD), LaCp₂(^{t}Bu₂AMD), LaCp₂(ⁱPr₂FMD), LaCp₂(^{t}Bu₂FMD), La(MeCp)₂(ⁱPr₂AMD), La(MeCp)₂(^{t}Bu₂AMD), La(MeCp)₂(ⁱPr₂FMD), La(MeCp)₂(^{t}Bu₂FMD), La(EtCp)₂(ⁱPr₂AMD), La(EtCp)₂(^{t}Bu₂AMD), La(EtCp)₂(ⁱPr₂FMD), La(EtCp)₂(^{t}Bu₂FMD), La(ⁱPrCp)₂(ⁱPr₂AMD), La(ⁱPrCp)₂(^{t}Bu₂AMD), La(ⁱPrCp)₂(ⁱPr₂FMD), La(ⁱPrCp)₂(^{t}Bu₂FMD), La(^{t}BuCp)₂(ⁱPr₂AMD), La(^{t}BuCp)₂(^{t}Bu₂AMD), La(^{t}BuCp)₂(ⁱPr₂FMD), and La(^{t}BuCp)₂(^{t}Bu₂FMD).

In some embodiments, the metal coordination compound comprises at least one of, or may be selected from a list consisting of: LuCp₃, Lu(MeCp)₃, Lu(EtCp)₃, Lu(ⁱPrCp)₃, Lu(acac)₃, Lu(thd)₃, Lu(OiPr)₃, Lu(OtBu)₃, Lu(N(SiMe₃)₂)₃, Lu(Et₂FMD)₃, Lu(ⁱPr₂FMD)₃, Lu(^{t}Bu₂FMD)₃, Lu(ⁱPr₂AMD)₃, Lu(^{t}Bu₂AMD)₃, LuCp₂(ⁱPr₂FMD), Lu(MeCp)₂(ⁱPr₂FMD), Lu(EtCp)₂(ⁱPr₂FMD), Lu(ⁱPrCp)₂(ⁱPr₂FMD), LuCp₂(ⁱPr₂AMD), Lu(MeCp)₂(ⁱPr₂AMD), Lu(EtCp)₂(ⁱPr₂AMD), and Lu(ⁱPrCp)₂(ⁱPr₂AMD).

In some embodiments, the metal coordination compound comprises at least one of, or may be selected from a list consisting of: TiF₄, TiCl₄, TiBr₄, TiI₄, Ti(NMe₂)₄, Ti(NEtMe)₄, Ti(NEt₂)₄, Ti(OMe)₄, Ti(OEt)₄, Ti(OⁱPr)₄, Ti(OtBu)₄, Ti(MeCp)(OⁱPr)₃, TiCp*(OMe)₃, TiCp(NMe₂)₄, Ti(EtCp)(NMe₂)₄, Ti(OⁱPr)₂(NMe₂)₂, Ti(OⁱPr)₂(thd)₂, Ti(OⁱPr)₃(ⁱPr₂AMD), and Ti(Np)₄.

In some embodiments, the metal coordination compound comprises at least one of, or may be selected from a list consisting of: ZrCl₄, ZrI₄, Zr(NMe₂)₄, Zr(NEtMe)₄, Zr(NEt₂)₄, Zr(thd)₄, Zr(OⁱPr)₄, Zr(O^{t}Bu)₄, ZrCp(NMe₂)₃, Zr(MeCp)(NMe₂)₃, Zr(EtCp)(NMe₂)₃, ZrCp(NEt₂)₃, Zr(MeCp)(NEt₂)₃, Zr(EtCp)(NEt₂)₃, ZrCp(NEtMe)₃, Zr(MeCp)(NEtMe)₃, Zr(EtCp)(NEtMe)₃, ZrCp₂Cl₂, ZrCp₂Me₂, ZrCp₂(OMe)₂, ZrCp₂Me(OMe), ZrCp₂(NMe₂)₂, Zr(MeCp)₂Cl₂, Zr(MeCp)₂Me₂, Zr(MeCp)₂(OMe)₂, Zr(MeCp)₂Me(OMe), Zr(MeCp)₂(NMe₂)₂, Zr(EtCp)₂Cl₂, Zr(EtCp)₂Me₂, Zr(EtCp)₂(OMe)₂, Zr(EtCp)₂Me(OMe), Zr(EtCp)₂(NMe₂)₂, ZrNp₄, and ZrCp(^{t}Bu₂DAD)(OⁱPr).

In some embodiments, the metal coordination compound comprises at least one of, or may be selected from a list consisting of: HfC14, Hfl4, Hf(NMe₂)₄, Hf(NEtMe)₄, Hf(NEt₂)₄, Hf(thd)₄, Hf(OⁱPr)₄, Hf(O^{t}Bu)₄, Hf(BH₄)₄, HfCp(NMe₂)₃, Hf(MeCp)(NMe₂)₃, Hf(EtCp)(NMe₂)₃, HfCp(NEt₂)₃, Hf(MeCp)(NEt₂)₃, Hf(EtCp)(NEt₂)₃, HfCp(NEtMe)₃, Hf(MeCp)(NEtMe)₃, Hf(EtCp)(NEtMe)₃, HfCp₂Cl₂, HfCp₂Me₂, HfCp₂(OMe)₂, HfCp₂Me(OMe), HfCp₂(NMe₂)₂, Hf(MeCp)₂Cl₂, Hf(MeCp)₂Me₂, Hf(MeCp)₂(OMe)₂, Hf(MeCp)₂Me(OMe), Hf(MeCp)₂(NMe₂)₂, Hf(EtCp)₂Cl₂, Hf(EtCp)₂Me₂, Hf(EtCp)₂(OMe)₂, Hf(EtCp)₂Me(OMe), Hf(EtCp)₂(NMe₂)₂, Hf(MeCp)₂(mmp)Me, Hf(O^{t}Bu)₂(mmp)₂, Hf(ⁱPr₂FMD)₂(NMe₂)₂, HfNp₄, Hf(dmap)₄, and Hf(mmp)₄.

In some embodiments, the metal coordination compound comprises at least one of, or may be selected from a list consisting of: TaF₅, TaCl₅, TaBr₅, Tal₅, Ta(NMe₂)₅, Ta(NEt₂)₅, Ta(NEtMe)₅, Ta(N^{t}Bu)(NMe₂)₃, Ta(N^{t}Bu)(NEt₂)₃, Ta(N^{t}Bu)(NEtMe)₃, Ta(NⁱPr)(NEtMe)₃, Ta(N^{t}Pn)(NMe₂)₃, Ta(OEt)₅, TaNp₃Cl₂, Ta(N^{t}Bu)Cl₃, Ta(N^{t}Pn)Cl₃, and Ta(N^{t}Bu)(ⁱPr₂AMD)₂(NMe₂).

In some embodiments, the metal coordination compound comprises at least one of, or may be selected from a list consisting of: Mg(acac)₂, Mg(hfac)₂, Mg(thd)₂, MgCp₂, Mg(MeCp)₂, Mg(EtCp)₂, Mg(ⁱPr₂AMD)₂, Mg(^{s}Bu₂AMD)₂, Mg(^{t}Bu₂AMD)₂, Mg(ⁱPr₂DAD)₂, Mg(^{t}Bu₂DAD)₂, and Mg(^{s}Bu₂DAD)₂.

In some embodiments, the metal coordination compound comprises at least one of, or may be selected from a list consisting of: MoCl₅, MoF₆, MoO₂Cl₂, bis(ethylbenzene)molybdenum, Mo(CO)₆, MoH₂(ⁱPrCp)₂, Mo(MeCp)(CO)₂(NO), Mo(N^{t}Bu)₂(NEt₂)₂, Mo(N^{t}Bu)₂(NMe₂)₂, and Mo(NMe₂)₄.

In some embodiments, the metal coordination compound comprises at least one of, or may be selected from a list consisting of: WCl₅, WF₆, WCl₆, W(CO)₆, W(CO)(3-hexyne)₃, W(N^{t}Bu)₂(NMe₂)₂, W(N^{t}Bu)₂(NMe₂)₂, W(N^{t}Bu)₂(ⁱPrAMD)₂, W(N^{t}Bu)₂(NEt₂)₂, WH₂Cp₂, W₂(NMe₂)₆, WH₂(ⁱPrCp)₂, WO₂Cl₂, and WO₂(^{t}BuAMD)₂.

In some embodiments, the metal coordination compound may be oxygen-free.

In some embodiments, the deposition method is a chemical vapor deposition process, such as atomic layer deposition (ALD). In CVD, typically, a reaction takes place between the substrate and the coordination compound, i.e., between the substrate and the borohydride coordination compound and/or between the substrate and the metal coordination compound. In some embodiments, the deposition method is a cyclic deposition process, such as ALD. In some embodiments, the method comprises, cyclically:
providing, into the reaction chamber, the vapor-phase metal precursor, then optionally purging the reaction chamber of the vapor-phase metal precursor, then providing, into the reaction chamber, the vapor-phase borohydride precursor, then optionally purging the reaction chamber of the vapor-phase borohydride precursor.

In some embodiments, during each cycle, the metal precursor is introduced into the reaction chamber and the metal coordination compound is chemisorbed onto the substrate surface (e.g., a substrate surface that may include a previously deposited material from a previous deposition cycle or other material). In some embodiments, the chemisorbed metal coordination compound on the substrate surface does not readily react with additional metal coordination compound (i.e., the deposition of the metal coordination compound may be a partially or fully self-limiting reaction).

Thereafter, the borohydride precursor may be introduced into the reaction chamber for converting the chemisorbed metal coordination compound to the desired material on the deposition surface. The borohydride coordination compound may be capable of further reaction with the chemisorbed metal coordination compound. In particular, the borohydride coordination compound of the present invention is adapted for substituting the substitutionally labile ligand of the chemisorbed metal coordination compound with the borohydride or the hydride from the borohydride coordination compound via transmetallation. The reaction of the chemisorbed metal coordination compound with the borohydride coordination compound may be self-limiting as the reaction may terminate when substantially no more substitutionally labile ligands are present on the substrate surface.

Thereafter, the metal precursor may again be introduced, thereby starting a new cycle. However, the invention is not limited thereto and, for example, alternatively, an optional further precursor or co-reactant may be introduced into the reaction chamber for reacting with the chemisorbed metal coordination compound after reaction or transmetallation with the borohydride coordination compound, and the metal precursor may only be provided again thereafter. In some embodiments, the cyclical method comprises a further step of:
introducing a further co-reactant into the reaction chamber, and then optionally purging the reaction chamber of the further co-reactant.

In some embodiments, the further co-reactant may be an oxygen containing compound, such as oxygen (O₂), water (H₂O), ozone (O₃), hydrogen peroxide (H₂O₂), or nitrous oxide (N₂O). In these embodiments, the deposited material may be a metal borate (MBₓO_{y}).

In some embodiments, the further co-reactant may be a nitrogen containing compound, such as ammonia (NH₃), hydrazine (N₂H₄), tert-butyl hydrazine, 1,1-dimethylhydrazine, or phenylhydrazine. In these embodiments, the deposited material may be a metal boronitride (MBₓN_{y}).

In some embodiments, the further co-reactant may be a carbon containing compound, such as an alkyl halide, an alkene, an alkyne, or a metal alkyl. In these embodiments, the deposited material may be a metal borocarbide (MBₓC_{y}).

Purging steps may be utilized during one or more cycles, e.g., during each step of each cycle, to remove any excess borohydride precursor and/or metal precursor and/or reaction byproducts from the reaction chamber. Thus, in some embodiments, the cyclic deposition process comprises purging the reaction chamber after providing a precursor into the reaction chamber. In some embodiments, the cyclic deposition process comprises purging the reaction chamber after providing the borohydride precursor into the reaction chamber. In some embodiments, the cyclic deposition process comprises purging the reaction chamber after providing the metal precursor into the reaction chamber.

The process may comprise one or more cyclic phases. In some embodiments, the process comprises one or more acyclic (i.e., continuous) phases. In some embodiments, the deposition process comprises the continuous flow of at least one precursor. In some embodiments, one or more of the precursors, e.g., the borohydride precursor and the metal precursor, are provided into the reaction chamber continuously.

In some embodiments, at least one of the borohydride precursor and the metal precursor is provided to the reaction chamber in pulses. In some embodiments, the borohydride precursor is supplied in pulses and the metal precursor is supplied in pulses, and the reaction chamber is purged between consecutive pulses of borohydride precursor and metal precursor. A duration of providing the borohydride precursor and/or the metal precursor into the reaction chamber (i.e., the borohydride precursor pulse time and the metal precursor pulse time, respectively) may be, for example, from about 0.01 seconds (s) to about 60 seconds, for example from about 0.01 s to about 5 s, or from about 1 s to about 20 s, or from about 0.5 s to about 10 s, or from about 5 s to about 15 s, or from about 10 s to about 30 s, or from about 10 s to about 60 s, or from about 20 s to about 60 s. The duration of the borohydride precursor or the metal precursor pulse may be, for example, for 0.03 s, 0.1 s, 0.5 s, 1 s, 1.5 s, 2 s, 2.5 s, 3 s, 4 s, 5 s, 8 s, 10 s, 12 s, 15 s, 25 s, 30 s, 40 s, 50 s or 60 s. In some embodiments, borohydride precursor pulse time may be at least 5 seconds, or at least 10 seconds. In some embodiments, borohydride precursor pulse time may be at most 5 s, or at most 10 s or at most 20 s, or at most 30 s. In some embodiments, metal precursor pulse time may be at least 5 s, or at least 10 s, or at least 20 s. In some embodiments, metal precursor pulse time may be at most 5 seconds, or at most 10 seconds or at most 20 s, or at most 30 s.

In some embodiments, providing the borohydride precursor and/or the metal precursor into the reaction chamber comprises pulsing the borohydride precursor and the metal precursor over the substrate. In some embodiments, the borohydride precursor may be pulsed more than one time, for example two, three or four times, before the metal precursor is pulsed to the reaction chamber. Similarly, there may be more than one pulse, such as, two, three, or four pulses, of the metal precursor before the borohydride precursor is pulsed (i.e., provided) into the reaction chamber.

In some embodiments, purging, for removing the vapor phase borohydride and metal precursor and/or vapor phase byproducts from the reaction chamber, may be performed by evacuating the reaction chamber with a vacuum pump and/or by replacing the gas inside the reaction chamber with an inert or substantially inert gas such as argon or nitrogen. Purging may be effected between two pulses of gases which react with each other. However, purging may be effected between two pulses of gases that do not react with each other. For example, a purge, or purging, may be provided between pulses of two precursors or between a precursor and a reactant. In some embodiments, purging may be performed after providing the borohydride precursor into the reaction chamber and before providing the metal precursor into the reaction chamber. In some embodiments, purging may be performed after providing the metal precursor into the reaction chamber and before providing the borohydride precursor into the reaction chamber. Purging may avoid or at least reduce gas-phase interactions between the two gases reacting with each other.

Purging may be effected either in time or in space, or both. In some embodiments, temporal purges are provided, wherein a purge step can be used, e.g., in the temporal sequence of providing the borohydride precursor to a reaction chamber, providing a purge gas to the reaction chamber, and providing the metal precursor to the reaction chamber, wherein the substrate on which a layer is deposited does not move. In some embodiments, spatial purges are provided, wherein a purge step can take the following form: moving a substrate from a first location to which the borohydride precursor is continually supplied, through a purge gas curtain or another means of separating the two spaces, to a second location to which the metal precursor is continually supplied. Purging times may be, for example, from about 0.01 seconds to about 20 seconds, from about 0.05 s to about 20 s, or from about 1 s to about 20 s, or from about 0.5 s to about 10 s, or between about 1 s and about 7 seconds, such as 5 s, 6 s or 8 s. However, other purge times can be utilized if necessary, such as where highly conformal step coverage over extremely high aspect ratio structures or other structures with complex surface morphology is needed, or in specific reactor types, such as a batch reactor, may be used.

In some embodiments, the chemical vapor deposition process may be characterized by vapor deposition which is not self-limiting. Such processes typically involve gas phase reactions between two or more precursors and/or reactants. The precursors, e.g., the borohydride precursor and the metal precursor, can be provided simultaneously to the reaction chamber or substrate, or in partially or completely separated pulses. In some embodiments, the borohydride precursor, or the metal precursor, or simultaneously the borohydride precursor and the metal precursor, is provided until a layer having a desired thickness is deposited.

The substrate being provided in the reaction chamber typically means that the substrate is in a space where deposition conditions can be controlled. The reaction chamber may be a single wafer reactor. Alternatively, the reaction chamber may be a batch reactor. The reaction chamber can form part of a vapor processing assembly for manufacturing semiconductor devices. The processing assembly may comprise one or more multi-station processing chambers. In some embodiments, the substrate is moved between processing stations of a multi-station processing chamber. The reaction chamber may be part of a cluster tool in which different processes are performed to form an integrated circuit. Various phases of the vapor deposition method can be performed within a single reaction chamber, or they can be performed in multiple reaction chambers, such as reaction chambers of a cluster tool, or deposition stations of a multi-station processing chamber.

In some embodiments, the reaction chamber is a semiconductor processing apparatus reaction chamber. In some embodiments, the reaction chamber may be a flow-type reactor, such as a cross-flow reactor. In some embodiments, the reaction chamber may be a showerhead reactor. In some embodiments, the reaction chamber may be a space-divided reactor. In some embodiments, the reaction chamber may be single wafer atomic layer deposition reactor. In some embodiments, the reaction chamber may be a high-volume manufacturing single wafer atomic layer deposition reactor. In some embodiments, the reaction chamber may be a batch reactor for manufacturing multiple substrates simultaneously.

The reaction chamber may form part of a vapor deposition system. The reaction chamber may form part of a chemical vapor deposition system. In some embodiments, said chemical vapor deposition is atomic layer deposition. The reaction chamber can form part of an atomic layer deposition system. In some embodiments, the system or the reaction chamber may be provided with a heater to activate reactions by elevating the temperature of one or more of the substrate and/or precursors.

The substrate may be a semiconductor wafer, such as a silicon wafer, a gallium arsenide wafer, a silicon carbide wafer, a germanium wafer, or an indium phosphide wafer, although the invention is not limited thereto. In some embodiments, the portion of the surface of the substrate is reactive towards borohydride coordination compound and/or metal coordination compound. In some embodiments, the portion of the surface of the substrate may be functionalized for facilitating chemical adsorption (or chemisorption) of the borohydride coordination compound and/or metal coordination compound. In some embodiments, the portion of the surface may be functionalized with a functional group selected from a group consisting of: hydroxyl groups, amino groups, carboxyl groups, thiols, silane groups, or combinations thereof. However, this is not essential, and instead, the borohydride coordination compound and/or metal coordination compound may be deposited without a reaction with the surface, or may be chemically deposited by reaction with a chemisorbed borohydride coordination compound and/or chemisorbed metal coordination compound.

Any features of any embodiment of the third aspect may be independently combined as correspondingly described for any embodiment of any of the other aspects of the present invention.

In a fourth aspect, the present invention relates to a system for depositing a material, the system comprising:
a reaction chamber for receiving the substrate,
a first source, connected via a first valve to the reaction chamber, for providing a vapor-phase borohydride precursor comprising a borohydride coordination compound with a chemical formula MH₃₋ₓ(BH₄)ₓ(NR¹R²R³), wherein M is a Group 13 metal, wherein x has a value of 2 or 3, and:
   wherein R¹, R², and R³ are each independently selected from C1 to C8 alkyl groups, or
   wherein R¹ together with R² and N forms a four to nine membered ring, and:
      R³ is selected from C1 to C8 alkyl groups, or
   R³ together with R² and N forms a four to nine membered ring, and a controller operably connected to the first valve, wherein the controller is configured and programmed to open the first valve to provide a flow of the vapor-phase borohydride precursor into the reaction chamber and to close the first valve to cease the flow of the vapor-phase borohydride precursor into the reaction chamber.

In some embodiments, the system is a semiconductor processing apparatus. In some embodiments, the reaction chamber comprises the substrate. The first source may comprise a borohydride precursor vessel that may be the precursor vessel in accordance with embodiments of the second aspect of the present invention.

The borohydride precursor vessel may have an inlet fluidically coupled to a source of a carrier gas. The carrier gas may be an inert gas such as N₂, He or Ar. The carrier gas may sweep a vapor of the borohydride precursor along with it through the borohydride precursor vessel outlet, into the reaction chamber.

The system may comprise heaters, that may be operated by a controller, for keeping the vapor-phase composition at or above the volatilization temperature of the borohydride precursor, throughout the deposition system so as to prevent undesirable condensation in the valves, filters, conduits, and other components associated with delivering the vapor-phase composition into the reaction chamber. In addition to a heater for heating the borohydride precursor vessel, as described elsewhere in the present description, additional heaters may be provided for heating the various valves and gas flow lines between the borohydride precursor vessel and the reaction chamber, to prevent the vapor-phase composition from condensing and depositing on such components. Gas-conveying components between the borohydride precursor vessel and the reaction chamber may be provided in which the temperature is maintained above the volatilization temperature of the borohydride precursor (i.e., “hot zone”).

In some embodiments, the system further comprises a second source, e.g., a metal precursor vessel, coupled to the reaction chamber via a second valve. Any features of any embodiment of the metal precursor vessel may be independently as correspondingly described for any embodiment of the precursor vessel of the second aspect of the present invention. The second source may be for providing a vapor-phase metal precursor into the reaction chamber. The second source may comprise, and/or be adapted for providing, a vapor-phase metal precursor comprising a metal coordination compound comprising:
a Group 2, transition, or lanthanide metal, and
a substitutionally labile ligand.

In these embodiments, the system may further comprise a controller operably connected to the second valve, wherein the controller is configured and programmed to open the second valve to provide a flow of the metal precursor into the reaction chamber and to close the second valve to cease the flow of the metal precursor into the reaction chamber.

In some embodiments, the system further comprises a device for purging the reaction chamber, such as a device for performing inert gas purging on the reaction chamber or a device for vacuum pumping the reaction chamber. The system may further comprise a controller for activating said purging device to purge the reaction chamber. The controller may be configured and programmed to purge the reaction chamber after closing of the first valve and before opening of the second valve, and/or after closing of the second valve and before opening of the first valve.

Any features of any embodiment of the fourth aspect may be independently combined as correspondingly described for any embodiment of any of the other aspects of the present invention.

In a fifth aspect, the present invention relates to a composition configured for depositing a thin film, the composition comprising a borohydride precursor comprising a borohydride coordination compound with a chemical formula MH₃₋ₓ(BH₄)ₓ(NR¹R²R³), wherein M is a Group 13 metal, wherein x has a value of 2 or 3, and:
wherein R¹, R² and R³ are each independently selected from C1 to C8 alkyl groups, or
wherein R¹ together with R² and N forms a four to nine membered ring, and:
   R³ is selected from C1 to C8 alkyl groups, or
   R³ together with R² and N forms a four to nine membered ring.

The compositions are typically stable enough for allowing the storage and use over an extended period of times, for example, over several months. The composition is typically adapted to withstand the deposition conditions to allow vapor transfer into a reaction chamber. Additionally, the vaporization rate of the composition under predetermined conditions remains preferably constant. Some compositions may suffer from more than one substance being vaporized from the composition. If the substances differ in volatility, the composition may be enriched in less volatile substances over time. This can lead to a phenomenon called process drift: one or more of the deposition process parameters gradually changes over time as the chemical composition of the composition changes. The consequences of process drift may be detrimental in sensitive applications, and the tuning of the process to compensate for the drift may be expensive, difficult, or even impossible.

In some embodiments, a purity of the composition, e.g., of the borohydride coordination compound, is at least 95 wt.-%, preferably at least 99 wt.-%, more preferably at least 99.9 wt.-%, even more preferably at least 99.99 wt.-%, still more preferably at least 99.999 wt.-%, yet more preferably at least 99.9999 wt.-%. Such high purities are typically strongly preferred for chemical vapor deposition, in particular, for atomic layer deposition.

Any features of any embodiment of the fifth aspect may be independently combined as correspondingly described for any embodiment of any of the other aspects of the present invention.

In a sixth aspect, the present invention relates to a method for depositing a material comprising a Group 2, transition, or lanthanide metal on a substrate, the method comprising:
providing a substrate in a reaction chamber, and then
providing, into the reaction chamber, a vapor-phase metal precursor comprising a metal coordination compound comprising:
the Group 2, transition, or lanthanide metal, and
a substitutionally labile ligand,
thereby forming a second thin film comprising the Group 2, transition, or lanthanide metal bonded to the ligand on a portion of a surface of the substrate, and then
providing, into the reaction chamber, a vapor-phase borohydride composition comprising a borohydride coordination compound, wherein:
when the substitutionally labile ligand is a halide, the borohydride coordination compound has a chemical formula MH₃₋ₓ(BH₄)ₓ(NR¹R²R³), wherein M is a Group 13 metal, wherein x has a value of from 2 to 3, wherein:
   wherein R¹, R², and R³ are each independently selected from C1 to C8 alkyl groups, or
   wherein R¹ together with R² and N forms a four to nine membered ring, and:
R³ is selected from C1 to C8 alkyl groups, or
   R³ together with R² and N forms a four to nine membered ring, and
when the substitutionally labile ligand is different from a halide, the borohydride coordination compound comprises:
   a Group 13 metal,
   a borohydride, and
   optionally a hydride,
thereby replacing the substitutionally labile ligand of the thin film with the borohydride or a hydride.

In some embodiments wherein the substitutionally labile ligand is different from a halide, the borohydride coordination compound may have the following chemical formula MH₃₋ₓ(BH₄)ₓ(NR¹R²R³), wherein M is a Group 13 metal, wherein x has a value of from 1 to 3, wherein:
wherein R¹, R², and R³ are each independently selected from C1 to C8 alkyl groups, or
wherein R¹ together with R² and N forms a four to nine membered ring, and:
R³ is selected from C1 to C8 alkyl groups, or
R³ together with R² and N forms a four to nine membered ring.

Any features of any embodiment of the sixth aspect may be independently combined as correspondingly described for any embodiment of any of the other aspects of the present invention.

### Example 1: Deposition of a Boride of a Group 2, Transition, or Lanthanide Metal

Embodiments of the present invention provide a novel method for depositing a thin film of a boride of a Group 2, transition, or lanthanide metal, such as rare-earth metal boride thin films, on a substrate (3).

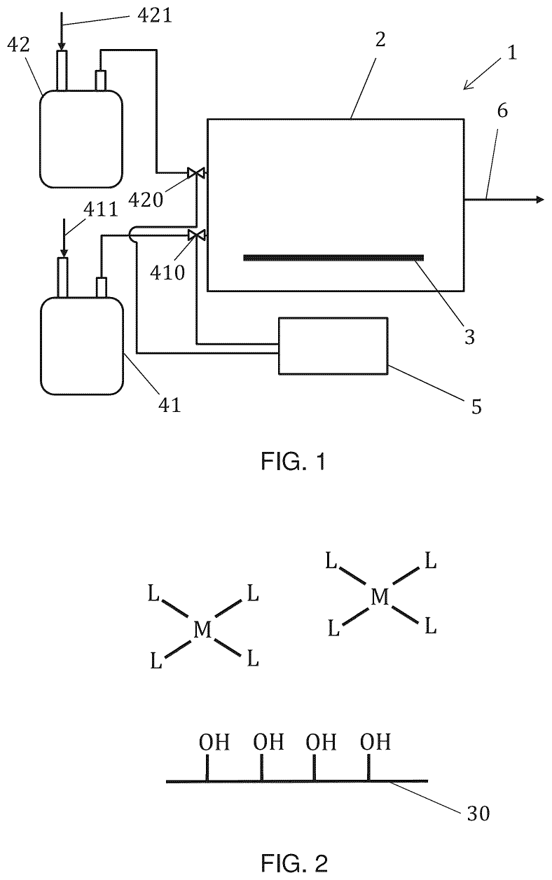

A schematic representation of a deposition system (1) in accordance with embodiments of the present invention is shown in FIG. 1.

The deposition system (1) comprises a reaction chamber (2) for receiving the substrate (3) on which the metal boride thin film is to be formed.

The deposition system (1) further comprises a first source (41) comprising a borohydride precursor vessel connected, at an outlet of the vessel, via a first valve (410) to the reaction chamber (2) for providing a borohydride vapor-phase precursor, that is, an aluminum borohydride vapor, and a controller (5) operably connected to the first valve (410). The controller (5) is configured and programmed to open and close the first valve (410) to control the flow of the vapor-phase borohydride precursor into the reaction chamber (2).

The deposition system (1) further comprises a second source (42) comprising a metal precursor vessel connected, at an outlet of the vessel, via a second valve (420) to the reaction chamber (2) for providing a vapor-phase metal precursor, comprising a metal coordination compound comprising a Group 2, transition, or lanthanide metal, and a substitutionally labile ligand. The deposition system (1) further comprises a controller (5) operably connected to the second valve (420). The controller (5) is configured and programmed to open and close the second valve (420) to control the flow of the vapor-phase metal precursor into the reaction chamber (2).

In the present example, the borohydride precursor comprises a borohydride coordination compound having the chemical formula M′H₃₋ₓ(BH₄)ₓ(NR¹R²R³). Preferably, the Group 13 metal M′ is aluminum. Preferably, x=3. Preferably, R¹ and R² are methyl groups, and R³ is an ethyl group. The inventors have found that, when the borohydride precursor has these features, the borohydride precursor has a particularly good thermal stability, and a particularly good ability to transfer borohydride units to the metal of the metal coordination compound. In the example shown, x=3, but x could alternatively be 2 or 1.

In the present example, the substitutionally labile ligand is a chemically stable ligand and may be easily substituted by transmetallation. Preferably, the substitutionally labile ligand is a good leaving group when coordinated to the Group 2, transition, or lanthanide metal, allowing for the exchange and transfer of the substitutionally labile ligands to the borohydride precursor.

Now, a cycle of deposition steps is described in accordance with embodiments of the present invention. The second valve (420) is opened by the controller (5). An inert carrier gas (421) is provided, via an inlet of the metal precursor vessel (42), into the metal precursor vessel (42), for inducing a flow of the metal precursor, through the outlet of the metal precursor vessel (42), through the second valve (420), into the reaction chamber (2). Instead of using the inert carrier gas, or in addition thereto, a flow of the metal precursor from the metal precursor vessel (42) into the reaction chamber (2) may be induced by providing a pressure difference between the metal precursor vessel (42) and the reaction chamber (2).

Simultaneous reference is made to FIG. 2, which schematically shows a top surface (30) of the substrate (3). In this example, the top surface (30) is functionalized with hydroxide groups. The vapor-phase metal precursor comprising the transition lanthanide metal M and the substitutionally labile ligands L is (as shown in FIG. 2) provided over said surface (30) to react with the surface (30).

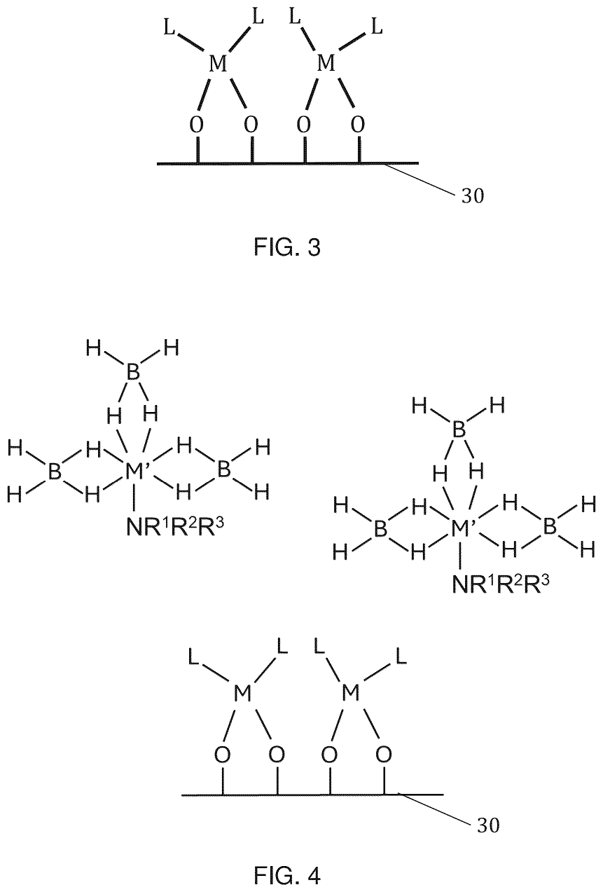

Thereby, as schematically shown in FIG. 3, a thin film is formed comprising the chemisorbed metal coordination compound. Herein, the metal M of the chemisorbed metal coordination compound is bonded to the surface (30). In some embodiments of the present invention, the chemisorbed metal coordination compound comprises the metal M bonded to one or more substitutionally labile ligands L. In the present example, the chemisorbed metal coordination compound comprises two substitutionally labile ligands L.

Next, the second valve (420) may be closed by the controller (5). The reaction chamber (2) may be purged of any non-chemisorbed metal precursor, e.g., any metal precursor that is still in the vapor-phase. Purging may, for example, be performed by removing vapor from the reaction chamber (2) via a reaction chamber outlet (6) that may, for example, be coupled to a vacuum pump.

Subsequently, the first valve (410) may be opened by the controller (5), and the vapor-phase borohydride precursor may be introduced into the reaction chamber (2), over the portion of the substrate surface (30), as shown in FIG. 4. For this, an inert carrier gas (411) may be introduced, through an inlet of the borohydride precursor vessel (41), into the borohydride precursor vessel (41), to provide a flow of the carrier gas together with the borohydride precursor, via an outlet of the borohydride precursor vessel (41), through the first valve (410), into the reaction chamber (2).

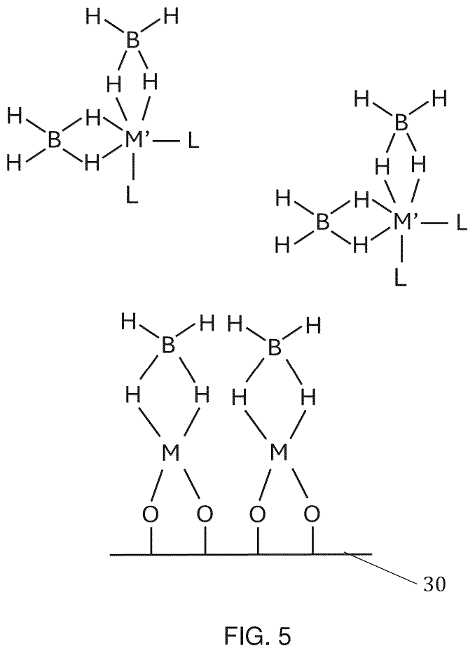

A transmetallation reaction takes place between the chemisorbed metal coordination compound, chemisorbed to the portion of the surface (30), and the borohydride coordination compound that may remain in the vapor phase. In particular, the substitutionally labile ligands L, originally bonded to the Group 2, transition, or lanthanide metal M on the surface (30), are replaced by the borohydride from the borohydride coordination compound, as schematically shown in FIG. 5. In turn, the substitutionally labile ligands L are, by said transmetallation, transferred and bonded to the Group 13 metal M′ of the borohydride coordination compound in the vapor-phase.

During said transmetallation, the amine NR¹R²R³ may leave the borohydride coordination compound. The amine preferably remains in the vapor phase and may be removed from the reaction chamber during a subsequent purge step.

Next, the first valve (410) may be closed by the controller (5) and the reaction chamber (2) may be purged of the borohydride precursor and any vapor-phase reaction products, including the transmetallated borohydride precursor and the amine.

The hydrogen atoms of the borohydride bonded to the Group 2, transition, or lanthanide metal M on the surface (30) may be removed so that the boron atom binds to the Group 2, transition, or lanthanide metal M for forming a metal boride.

Said removal of the hydrogen atoms may occur during the cyclic process (e.g., without requiring additional removal steps). For example, the hydrogen atoms may react with ligands L of the metal coordination compound during a next cycle of the cyclic deposition process. Said ligand L reacted with, or bonded to, the hydrogen atom may then be released from the metal coordination compound, remain in the vapor phase, and be removed during a subsequent purge step.

The hydrogen atom of the borohydride bonded to the Group 2, transition, or lanthanide metal M on the surface may be removed by thermal desorption or thermal elimination, which may result in the spontaneous release of the hydrides as part of a gas-phase by-product, such as H₂ or as a boron-hydrogen compound, e.g., borane or diborane.

The hydrogen atom of the borohydride bonded to the Group 2, transition, or lanthanide metal M on the surface may be removed by providing a vapor-phase co-reactant into the reaction chamber (2), wherein the co-reactant reacts with the hydrogen atom. The co-reactant may comprise, for example, a hydrogen plasma or hydrogen fluoride, which may efficiently remove hydrogen atoms from the deposited material. Alternatively, ozone, oxygen plasma, ammonia, a nitrogen plasma, could be used as co-reactant for said removing of hydrogen atoms, although these co-reactants could introduce oxygen or nitrogen impurities. Said step of removing the hydrogen atoms by providing a co-reactant may be performed during each cycle. For example, during each cycle, after providing the metal precursor and the borohydride precursor, and after an optional purging step for removing the metal precursor and/or borohydride precursor from the reaction chamber (2), the vapor-phase co-reactant may be provided into the reaction chamber (2). After reaction of the co-reactant with the hydrogen atom for removing the hydrogen atoms from the surface, the reaction chamber (2) may be purged of the co-reactant and any vapor-phase reaction products.

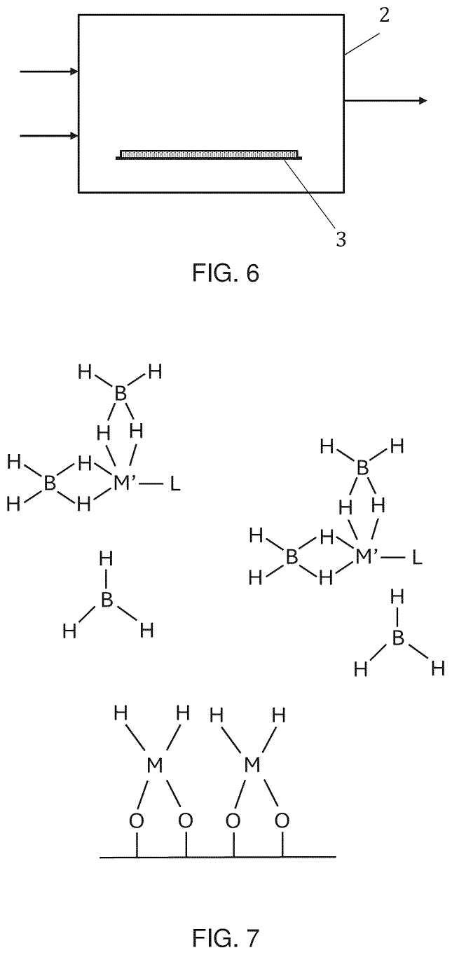

The above steps of providing the metal precursor and then the borohydride precursor, and optionally the co-reactant, with optional purging steps in-between, may be cyclically performed. This may result in the formation of a boride of the Group 2, transition, or lanthanide metal M on the substrate (3) in the reaction chamber (2), as schematically shown in FIG. 6.

Although in this example, a specific metal coordination compound, comprising four substitutionally labile ligands L, a similar reaction may take place for other metal coordination compounds in accordance with embodiments of the present invention, e.g., comprising less than four substitutionally labile ligands L or more than four substitutionally labile ligands L.

Although in this example, a specific borohydride coordination compound is shown comprises three borohydride groups, a similar reaction could proceed with other borohydride coordination compounds in accordance with embodiments of the present invention.

### Example 2: Deposition of a Group 2, Transition, or Lanthanide Metal

Reference is made back to FIG. 4, comprising the chemisorbed metal coordination compound, chemisorbed on the substrate surface (30), and the vapor-phase borohydride coordination compound over the substrate surface (30).

Although, in the above Example 1, a borohydride was transferred, via transmetallation in exchange for the substitutionally labile ligand L, from the borohydride coordination compound to the chemisorbed metal coordination compound, instead, a hydride could have been transferred, from the borohydride coordination compound to the chemisorbed metal coordination compound, to exchange the substitutionally labile ligand L. Whether the borohydride or the hydride is transferred, will largely depend on the reduction potential of the Group 2, transition, or lanthanide metal M, the relative stability of the deposited boride compared to the deposited (pure/metallic) Group 2, transition, or lanthanide metal, and on the selection of the substitutionally labile ligands L.

Within the present example in which the borohydride coordination compound has the chemical formula M′H₃₋ₓ(BH₄)ₓ(NR¹R²R³) with x=3, the hydride may originate from the borohydride of the borohydride precursor. When, instead, x=1 or 2, the borohydride coordination compound contains a hydride directly bonded to the Group 13 metal M′, and the hydride that exchanges the substitutionally labile ligands L of the chemisorbed Group 2, transition, or lanthanide metal coordination compound may instead be said hydride directly bonded to the Group 13 metal M′, or it may originate from the borohydride of the borohydride coordination compound.

FIG. 7 shows a possible result wherein hydride has been transferred from the borohydride of the vapor-phase borohydride coordination compound to the chemisorbed metal coordination compound, and a substitutionally labile ligand L has been transferred from the chemisorbed metal coordination compound to the vapor-phase borohydride coordination compound (only two molecules of the vapor-phase borohydride coordination compound are shown although four molecules of the vapor-phase borohydride coordination compound take part in the reaction). After removal of the hydride from the borohydride, the borohydride BH₄ is transformed into borane BH₃, which is uncharged and typically does not remain bonded to the Group 13 metal M′ of the vapor-phase borohydride coordination compound. Said borane leaves the Group 13 metal M′, before or during said transmetallation reaction, and may remain in the vapor-phase (where it may form vapor-phase B₂H₆ that is chemically more stable). Alternatively, after removal of the hydride from the borohydride BH₄, BH₃L could be formed as a vapor phase by-product, especially where the substitutionally labile ligand L contains an element with a lone pair of electrons that can coordinate to BH₃, such as oxygen or nitrogen.

The transfer of the hydride to the Group 2, transition, or lanthanide metal on the surface corresponds to reduction of the Group 2, transition, or lanthanide metal, which may yield a metallic layer of the Group 2, transition, or lanthanide metal.

It is to be understood that although preferred embodiments, specific constructions and configurations, as well as materials, have been discussed herein for devices according to the present invention, various changes or modifications in form and detail may be made without departing from the scope of this invention. Steps may be added or deleted to methods described within the scope of the present invention.

1. A composition comprising a borohydride coordination compound with a chemical formula MH₃₋ₓ(BH₄)ₓ(NR¹R²R³), wherein M is a Group 13 metal, wherein x has a value of 2 or 3, and:
wherein R¹ and R² are each independently selected from C1 to C8 alkyl groups, and wherein R³ is a C2 to C8 alkyl group, or
wherein R¹ together with R² and N forms a four to nine membered ring, and:
R³ is selected from C1 to C8 alkyl groups, or
R³ together with R² and N forms a four to nine membered ring.

2. The composition of claim 1, wherein M is aluminum.

3. The composition of claim 1, wherein x has a value of 3.

4. The composition of claim 1, wherein R¹ and R² are each independently selected from C1 to C3 alkyl groups and R³ is a C2 to C4 alkyl group.

5. The composition of claim 4, wherein R¹ and R² are each independently selected from C1 to C2 alkyl groups and R³ is a C2 to C3 alkyl group.

6. The composition of claim 5, wherein R¹ and R² are methyl groups and R³ is an ethyl group.

7. The composition of claim 1, wherein R¹, R², and N together form a five or six membered ring, and wherein R³ is a C1 to C6 alkyl group.

8. The composition of claim 7, wherein R¹, R², and N together form a five membered ring, and wherein R³ is a C1 to C3 alkyl group.

9. A precursor vessel comprising a borohydride precursor comprising a borohydride coordination compound with a chemical formula MH₃₋ₓ(BH₄)ₓ(NR¹R²R³), wherein M is a Group 13 metal, wherein x has a value of 2 or 3, and:
wherein R¹, R², and R³ are each independently selected from C1 to C8 alkyl groups, or
wherein R¹ together with R² and N forms a four to nine membered ring, and:
R³ is selected from C1 to C8 alkyl groups, or
R³ together with R² and N forms a four to nine membered ring,
wherein the precursor vessel is configured to supply a vapor comprising the borohydride precursor to a reaction chamber of a vapor deposition system.

10. A method for depositing a material on a substrate, the method comprising:
providing a substrate in a reaction chamber, and then
providing, into the reaction chamber, a vapor-phase borohydride precursor comprising a borohydride coordination compound with a chemical formula MH₃₋ₓ(BH₄)ₓ(NR¹R²R³), wherein M is a Group 13 metal, wherein x has a value of 2 or 3, and:
wherein R¹, R², and R³ are each independently selected from C1 to C8 alkyl groups, or
wherein R¹ together with R² and N forms a four to nine membered ring, and:
R³ is selected from C1 to C8 alkyl groups, or
R³ together with R² and N forms a four to nine membered ring,
thereby forming a first thin film comprising at least a portion of the borohydride coordination compound on a portion of a surface of the substrate.

11. The method of claim 10, comprising, before providing the vapor-phase borohydride precursor into the reaction chamber, a step of:
providing, into the reaction chamber, a vapor-phase metal precursor comprising a metal coordination compound comprising:
a Group 2, transition, or lanthanide metal, and
a substitutionally labile ligand,
thereby forming a second thin film comprising the Group 2, transition, or lanthanide metal bonded to the ligand on a portion of a surface of the substrate,
wherein said providing of the vapor-phase borohydride precursor into the reaction chamber comprises replacing the substitutionally labile ligand of the second thin film with the borohydride or a hydride, thereby forming the first thin film.

12. The method of claim 10, wherein the substitutionally labile ligand is a bidentate ligand.

13. The method of claim 12, wherein the substitutionally labile ligand is bonded with two atoms each independently selected from oxygen and nitrogen to the metal.

14. The method of claim 13, wherein the substitutionally labile ligand is a diketonate.

15. The method of claim 14, wherein the substitutionally labile ligand is an optionally substituted acetylacetonate.

16. The method of claim 15, wherein the substitutionally labile ligand is 2,2,6,6-tetramethyl-3,5-heptanedionate.

17. The method of claim 10, wherein the Group 2, transition, or lanthanide metal is selected from a group consisting of Group 3, Group 4, Group 5, and Group 6 metals, and lanthanides.

18. The method of claim 17, wherein the Group 2, transition, or lanthanide metal is a rare earth metal.

19. A system for depositing a material, the system comprising:
a reaction chamber for receiving the substrate,
a first source, connected via a first valve to the reaction chamber, for providing a vapor-phase borohydride precursor comprising a borohydride coordination compound with a chemical formula MH₃₋ₓ(BH₄)ₓ(NR¹R²R³), wherein M is a Group 13 metal, wherein x has a value of 2 or 3, and:
wherein R¹, R² and R³ are each independently selected from C1 to C8 alkyl groups, or
wherein R¹ together with R² and N forms a four to nine membered ring, and:
R³ is selected from C1 to C8 alkyl groups, or
R³ together with R² and N forms a four to nine membered ring, and
a controller operably connected to the first valve, wherein the controller is configured and programmed to open the first valve to provide a flow of the vapor-phase borohydride precursor into the reaction chamber and to close the first valve to cease the flow of the vapor-phase borohydride precursor into the reaction chamber.

20. A composition configured for depositing a thin film, the composition comprising a borohydride precursor comprising a borohydride coordination compound with a chemical formula MH₃₋ₓ(BH₄)ₓ(NR¹R²R³), wherein M is a Group 13 metal, wherein x has a value of 2 or 3, and:
wherein R¹, R², and R³ are each independently selected from C1 to C8 alkyl groups, or
wherein R¹ together with R² and N forms a four to nine membered ring, and:
R³ is selected from C1 to C8 alkyl groups, or
R³ together with R² and N forms a four to nine membered ring.
